(19) United States
(12) Patent Application Publication
(10) Pub. No.: US 2014/0069844 A1
(43) Pub. Date: Mar. 13, 2014

(54) CIRCUIT BOARD MAGAZINE HAVING RETENTION BAR WITH A LOCKING MECHANISM

(71) Applicant: MEDTRONIC, INC., Minneapolis, MN (US)

(72) Inventors: James B. Kida, Phoenix, AZ (US); Jose DeVera, Phoenix, AZ (US)

(73) Assignee: MEDTRONIC, INC., Minneapolis, MN (US)

(21) Appl. No.: 13/826,072

(22) Filed: Mar. 14, 2013

Related U.S. Application Data
(60) Provisional application No. 61/697,831, filed on Sep. 7, 2012.

(51) Int. Cl. H01L 21/673

(52) U.S. Cl. CPC H01L 21/67333
USPC 206/707

(57) ABSTRACT

A circuit board magazine for carrying electronic articles, such as printed circuit boards and the like having a plurality of slots arranged in stacked parallel relationship for receiving the electronic articles is provided. The plurality of slots are formed as a pair of oppositely facing recessed regions extending along the length of the device. Each of the slots includes a recessed region that receives an edge of the printed circuit boards. An engagement mechanism is mounted at an open end face of the device. The engagement mechanism includes a retention bar and a spring-loaded lever that is pivotally mounted for automatic movement to a raised inoperative position to disengage the retention bar and permit the bar to swivel freely. In a retracted position, the retention bar permits passage of the printed circuit boards through the open end face. In the closed position, the retention bar prevents movement of the circuit boards from the interior of the device.

### FIELD

The present disclosure pertains generally to devices for carrying electronic articles, such as printed circuit boards and the like. In particular, the disclosure pertains to an assembly line magazine that protects the integrity of the circuit boards and facilitates compact storage and transportation of the boards during or after manufacture.

### BACKGROUND

Circuit boards are widely used in the electronics industry to support and interconnect electronic components and often need to be handled in batches of large numbers. It is, therefore, convenient to arrange the circuit boards in uniform stacks such that they are parallel to and uniformly spaced apart from each other, in order to minimize their stored or processed volume. Circuit board magazines designed to accommodate a number of boards so arranged can be stored, transported or otherwise handled as necessary, without handling of the individual circuit boards in the magazine.

The circuit boards are securely held in the circuit board magazines, albeit being readily removable therefrom. The magazine includes grooves that are suitably arranged to interact with the edges of the circuit boards and hold the boards in place. The free ends of the circuit boards are securely held in place by a removable end cap (plate) of the magazine. The end caps have to be coupled to the magazine whenever the magazine is moved from station to station along the manufacturing line. In addition, the end caps have to be disengaged from the magazine each time the circuit boards are loaded onto and unloaded from the magazine. As a result of the continuous removal and re-attachment, the end caps need to be cleaned to ensure no foreign material builds up onto the end caps which may be inadvertently transferred onto the circuit boards.

Conventional magazines have been observed by the inventors of the present application to cause damage to the circuit boards. For example, because the magazines use end caps that are removeable, such as through sliding action, the interaction of the end cap with the magazine and/or circuit board edges has been observed to cause shaving of particles from the end-cap plates, the magazine and the circuit board(s) which can leave deposits on the circuit boards or even damage the boards. In particular, this damage occurs due to the interaction between the exposed free edges of the circuit boards and the moveable plate, for example, during loading and unloading of the circuit boards onto the magazine. Alignment of the end caps is an issue. If misaligned, the caps scrap the magazine resulting in chaffing of particles from the end cap or the magazine or both which may be transferred onto the component. Accordingly, there remains a need for improved magazines that protect the structural integrity of the circuit boards.

### SUMMARY

The disclosure provides a circuit board magazine that allows a plurality of circuit boards that may be disposed in a side-by-side relationship to be held in the magazine by virtue of coaction of the opposing edge-parts of respective circuit boards with particularly configured grooves or channels in the magazine edges. Each circuit board is slidably inserted into the magazine's interior from a first open end-face of the magazine, such as a front open end, to a second open end-face of the magazine that may be opposite the first open end-face, such as a back open end.

In accordance with an embodiment, a circuit board magazine is provided with a frame. The frame comprises four plates that are spaced apart to include a base plate opposing a top plate with the base and top plates being coupled to opposing first and second side plates—this configuration defines a rectangular housing. The magazine includes a first open end and a second open end on opposing first and second planes. The first and second planes may correspond to the front open end and the back open end, respectively, or vice versa. In further aspects, the magazine may include a first engagement-mechanism at the front open end. In accordance with another embodiment, a circuit board magazine includes a second engagement-mechanism at the back open end. The first and second engagement-mechanisms engage with the edges of the circuit board that are adjacent to prevent movement of the circuit boards within, or away from, the interior of the magazine.

An engagement-mechanism, such as the first and second engagement-mechanisms, in accordance with aspects of this disclosure may include a retention bar coupled at one end of the first or second plane with a lock lever. The lock lever may interact with the retention bar to selectively restrict movement of the retention bar. In one embodiment, the retention bar may include a groove into which the lock lever is inserted to engage the retention bar and inhibit movement of the retention bar. In a first position, the lock lever causes the retention bar to be placed in a closed position whereas, in the second position, the lock lever causes the retention bar to be placed in an open position. The retention bar is coupled to the magazine such that when disengaged from the lock lever, the retention bar is permitted to swivel from the closed position, generally towards the open end of the magazine, to the open position, generally towards a side-face of the magazine.

In further aspects of the disclosure, the engagement mechanism includes a detent that prevents placement of the magazine onto an onloader or offloader with the retention bar in a closed position. This prevents the risk of accidently offloading the boards with the retention bar in the closed position which would damage the boards.

This summary is intended to provide an overview of the subject matter described in this disclosure. It is not intended to provide an exclusive or exhaustive explanation of the techniques as described in detail within the accompanying drawings and description below. Further details of one or more examples are set forth in the accompanying drawings and the description below. Other features, objects, and advantages will be apparent from the description and drawings, and from the statements provided below.

### BRIEF DESCRIPTION OF THE DRAWINGS

The following drawings are illustrative of particular embodiments of the present invention and therefore do not limit the scope of the invention. The drawings are not to scale (unless so stated) and are intended for use in conjunction with the explanations in the following detailed description. Embodiments will hereinafter be described in conjunction with the appended drawings wherein like numerals/letters denote like elements, and:

FIG. 1 is a front perspective view of the magazine;

FIG. 2 is an exploded front perspective view of the magazine of FIG. 1; and

FIG. 3 is a top perspective view of the magazine.

### DETAILED DESCRIPTION

The disclosure describes a circuit board magazine that is constructed to enable one or more self-supporting articles such as circuit boards and the like to be held firmly in the magazine but readily removable therefrom. As used in this specification and the concluding claims, it is understood that the term self-supporting means a thin member having appreciable width and depth that can be supported generally horizontally at its edges without collapsing under its own weight and the weight of other objects that it is intended to carry.

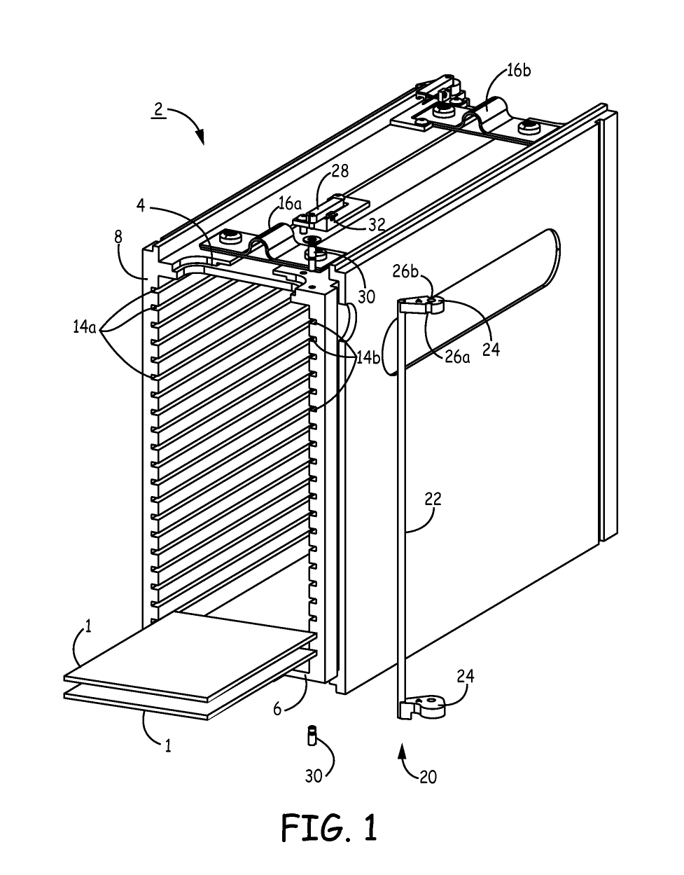

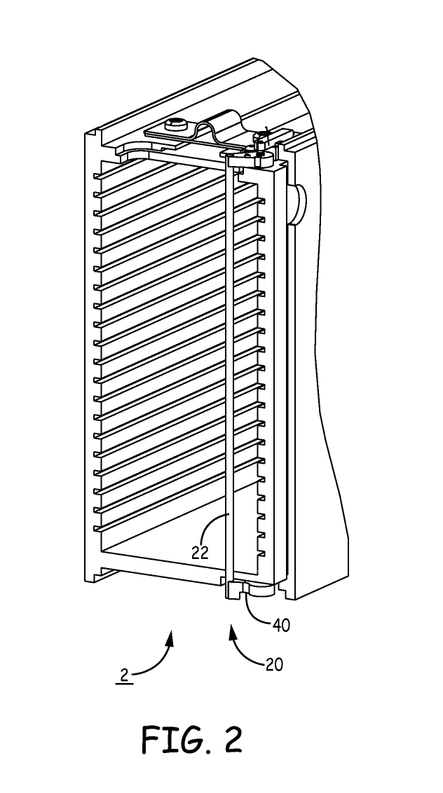

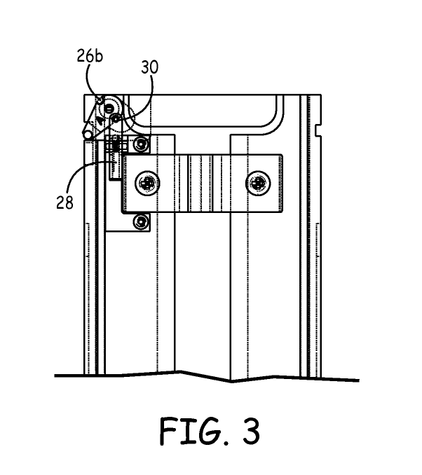

FIGS. 1, 2, 3 show an embodiment of a magazine of the present disclosure for carrying self-supporting articles. FIG. 1 is a front perspective view of the magazine, FIG. 2 is an exploded front perspective view of the magazine of FIG. 1, and FIG. 3 is a top perspective view of the magazine. For convenience, the following description will be made with reference to use of the magazine specifically for circuit boards. The magazine will normally accommodate a plurality of self-supporting articles in a stacked relationship, although for the sake of clarity only one circuit board is shown in FIG. 1, this circuit board being shown partially inserted. However, it will be understood that this magazine may be used to store or otherwise support other self-supporting, sheet-like articles, such as a thin member having appreciable width and depth that can be supported generally in a single plane, e.g., horizontally, at its edges without collapsing under its own weight and the weight of other objects that it is intended to carry.

In the embodiment of FIG. 1, a magazine 2 generally includes a top panel 4 and a bottom panel 6 coupled to opposing first and second side panels 8. The side panels 8 meet with the top panel 4 and bottom panel 6 at about 90 degree angles. The top panel 4, bottom pane 6, and first and second side panels 8 generally define a hollow rectangular frame 10 with an open front face and an open back face. The top panel 4, bottom pane 6, and first and second side panels 8 provide structural rigidity for the magazine 2 to prevent damage to circuit board(s) 1 that are placed within the rectangular frame.

The top and bottom panels 4, 6 support the side panels 8 in a face-to-face relation, spaced apart by a defined distance. The distance may be defined based on a width of the articles for which the magazine 2 is to be used. In other words, the dimensions, in particular, width, for the top panel 4 and bottom panel 6 can be configured to support any desired width for the circuit boards. Alternatively, the coupling of the side panels 8 may be dynamically adjustable based on the width of the circuit boards. Such a feature makes it possible to select the spacing between the side panels 8 to accommodate circuit boards of various dimensions. The side panels 8 may be secured to the top and bottom panels 4, 6 in any suitable manner such as by welding or screws.

Two or more pairs of mutually opposed horizontal slots 14a and 14b are formed on the side panels 8. The slots 14a, 14b are formed having a width that is at least equal to or greater than the width of the circuit boards. In use, each opposing slot 14a, 14b defines a track onto which each circuit board 1 can be inserted into and withdrawn from the magazine through the interaction of the edges of each board 1 engaging with the corresponding slots 14a, 14b of the magazine 2. The circuit board edges having been slid as such on opposing side panels 8 are securely carried by the magazine 2. The slots 14a, 14b in each pair are formed at an identical height on the side panels 8. Each opposing slot of the pair 14a, 14b receives one edge of a circuit board. The slots 14a, 14b extend from the front to the back of the magazine 2 in the embodiment of FIG. 1 and the opposing slots 14a, 14b in opposing side panels 8 thereby define a plurality of parallel edge supports for the circuit boards.

Two brackets 16a, 16b are coupled to the first (or second) side panel 8. The brackets 16 are aligned to permit a shaft to be received therethrough. The brackets may facilitate conveying of the magazine 2, for example, along an assembly line. It will be appreciated that the brackets 16, in addition to providing an easy means for transportation of the magazine, can be used to suspend it for storage, and also provide extra rigidity in the side-to-side direction. The positioning of the brackets 16 may also facilitate holding of the magazine 2 securely in complementary portions of a loader or off-loader, making it possible to insert the circuit boards into the magazine.

Each of the top panel 4, bottom panel 6, and side panels 8 in the embodiment of FIG. 1 is preferably a substantially planar element, made of a sheet metal or any other suitably rigid sheet-like material including iron, aluminum, brass and stainless steel.

An engagement mechanism 20 may be provided to secure the circuit board(s) within the magazine 2. The engagement mechanism 20 includes a retention bar 22, a pair of pivot members 24, and a lock lever 28. Unlike the end caps of the prior art, the retention bar 22 is formed as part of the magazine. Therefore, it is just swiveled to lock the components in place or in the opposite direction to unload the components from the magazine. The retention bar 22 is coupled at first and second ends to the pivot members 24 in a fixed relation. Such coupling may be achieved through welding, for example. A pivot shaft 30a, 30b is provided for fixedly coupling to each of the pivot members 24. The pivot members 24 include an opening that is sized to receive the pivot shaft 30. The opening of the pivot member 24 includes dimensions that are sized to freely permit rotation of the pivot members 24 about the pivot shaft 30 while the pivot shaft 30 is inserted through the opening.

The lock lever 28 may be coupled to the panel 4 through a torsion spring assembly 32 that may include a shaft coupled to the side panel 8 onto which a spring is mounted. The torsion spring assembly 32 enables the lock lever 28 to be selectively engaged and disengaged from the pivot member 24. In turn, the engagement of the locking lever 28 with the pivot member 24 inhibits movement of the retention bar 22 and disengagement of the locking lever 28 from the pivot member 24 permits free movement of the retention bar 22 about the pivot shaft 30.

The materials for the constituent components of the engagement mechanism 20 may be selected to match the materials of the panels. Such materials may include metals such as iron, brass, stainless steel, aluminum or any other rigid material that will not permit flexing against the weight of the circuit boards disposed within the magazine 2 and that is compatible with the material of the panels to enable the aforementioned coupling to the top and bottom panels.

Turning to the embodiment shown in FIG. 3, portions of the engagement mechanism are illustrated. In particular, the pivot member 24 is shown having first and second grooves 26a, b. The pivot member 24 swivels about a generally circumferential plane so that the lock lever can be inserted into one of the first and second grooves 26a, b.

When inserted into either one of first or second grooves 26a, b, the swiveling movement of the pivot member 24 is inhibited. As illustrated in FIGS. 1, 2, and 3, the retention bar 22 is fixedly coupled to the pivot member 24 such that the swiveling motion of the pivot member 24 is directly translated into movement in the same direction of the retention bar 22. Similarly, inhibiting the movement of the pivot member 24 causes the retention bar 22 to remain in a fixed location. When positioned in the closed position, the retention bar 22 secures the circuit boards within the magazine 2.

In an embodiment, one such engagement mechanism 20 is provided at the front open end and another engagement mechanism 20 may be provided at the back open end.

Each engagement mechanism 20 is independently operable to permit insertion of the circuit boards through the front open end or the back open end and removal through either open ends.

The lock lever 28 is inserted into the first groove 26a which coincides with the retention bar 22 being in a retracted position. In the retracted position, the retention bar 22 allows circuit boards to be inserted into or removed from the slots 14 of the side panels 8. When the circuit boards have been loaded, the lock lever is raised to disengage from the first groove 26a and the retention bars 22 on the front open end and the back open end are swiveled inward toward the open ends to contact the immediately-adjacent edges of the circuit boards. The lock lever 28 is inserted into the second groove 26b to again engage the retention bar 22. Once this has been done, the retention bars 22 function as stops to prevent the circuit boards from falling out of the magazine 2.

The locking action of the retention bar 22 is advantageous in that no sliding action occurs when securing the circuit boards 1. Rather, the swiveling action simply causes the retention bar 22 to abut the circuit boards 1. As such, no shaving of the circuit boards occurs.

In another embodiment, the engagement mechanism 20 includes a detent 40 that prevents placement of the magazine 2 onto a handler of the onloader or offloader with the retention bar(s) 22 in a closed position. The detent 40 abuts with a feature of the handler to prevent the magazine 2 from being inadvertently placed within the onloader or offloader with the retention bar(s) 22 in the closed position. This prevents the risk of accidently offloading the boards with the retention bar in the closed position which would damage the boards.

Although specific embodiments have been illustrated and described, those skilled in the art will appreciate that various modifications may be made without departing from what is intended to be limited solely by the appended claims. Accordingly, the claims are not limited by the disclosure. The benefits, advantages, solutions to problems, and any element(s) that may cause any benefit, advantage, or solution to occur or become more pronounced are not to be construed as a critical, required, or essential features or elements of any or all of the claims. As used herein, the terms “comprises,” “comprising,” “having,” “including,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A circuit board magazine for carrying self-supporting articles such as circuit boards, comprising:
a top panel and a bottom panel;
a pair of side panels each having a first end and a second end, each of the top and bottom panels being coupled to the first and second ends to define a generally rectangular frame, wherein each of the side panels is formed with a plurality of recessed slots with corresponding pairs of recessed slots on each side panel being positioned in a generally perpendicular plane;
an engagement mechanism coupled pivotally at a first open end of the rectangular frame to permit passage of the circuit boards into the recessed slots in response to the engagement mechanism being retracted and to secure the circuit boards within an interior of the rectangular frame in response to the engagement mechanism being in a closed position, wherein the engagement mechanism includes a retention bar and a lock lever.

2. The magazine of claim 1, wherein the engagement mechanism further includes a detent for guiding the seating of the magazine within a magazine handler.

3. The magazine of claim 1, wherein the lock lever of the engagement mechanism includes a compressible spring that permits selective engagement of the retention bar in response to a compression force.

4. The magazine of claim 1, further comprising a handle supported by the generally rectangular frame.

5. The magazine of claim 1, further comprising a guiderail coupled to at least one of the top panel, the bottom panel, or the pair of side panels.

6. The magazine of claim 1, further comprising handle means for gripping to carry the magazine.

7. The magazine of claim 1, wherein the engagement mechanism includes a pivoting means projecting in an inward direction with respect to the magazine, the pivoting means being normally biased in a contracted position to engage the lock lever.

8. The magazine of claim 7, wherein the pivoting means is raised in response to application of a downward force.
